(19) United States
(12) Patent Application Publication
(10) Pub. No.: US 2010/0315091 A1
(43) Pub. Date: Dec. 16, 2010

(54) Detecting a Short Circuit in an Inductive Load Current Path

(76) Inventors: Heimo Hartlieb, Graz (AT); Michael Hausmann, Gleisdorf (AT)

Correspondence Address: SLATER & MATSIL, L.L.P., 17950 PRESTON ROAD, SUITE 1000, DALLAS, TX, 75252, US

(21) Appl. No.: 12/483,917

(22) Filed: Jun. 12, 2009

(51) Int. Cl. G01R 31/02

(52) U.S. Cl. 324/509

(57) ABSTRACT

A method detects a short circuit in a load current path that includes an inductive load.

### TECHNICAL FIELD

The present invention relates to detecting a short circuit in an inductive load current path, in particular, a load current path in a current controller, and to a current controller having a short circuit detection capability.

### BACKGROUND

A current through an inductive load can be controlled by applying a pulsewidth-modulated supply voltage to the load, and by controlling the duty cycle of the supply voltage dependent on the current flowing through the load. The pulse-width modulated (PWM) supply voltage alternatingly assumes a high voltage level for an on-period and a low voltage level for an off-period, with the current through the load increasing during the on-period and decreasing during the off-period. A mean value of the current through the load can be adjusted by varying the duty cycle of the PWM supply voltage.

During operation of the load a short circuit may occur. Such a short circuit may be detected by comparing the current flowing through the load with a threshold value, where the presence of a short circuit is detected, if the current reaches the threshold or rises above the threshold. However, at the beginning of the on-period current swings may occur, resulting in the current rising above the threshold level for a short period. In order to avoid such current swings from erroneously resulting in detection of a short circuit, the short circuit detection may be modified such that the presence a short circuit is only detected, if the current stays above the threshold for a given time. However, this delays short circuit detection so that there is the risk of the load current rising to critical values.

### SUMMARY OF THE INVENTION

A first aspect relates to a method for detecting a short circuit in a load current path, the load current path including an inductive load. The method comprises: applying a pulse-width modulated supply voltage to the load path, the supply voltage alternatingly assuming a first voltage level for an on-period and a second voltage level for an off-period; measuring a current flowing in the load path and providing a measurement signal being dependent on this current; integrating the measurement signal over an evaluation period for obtaining an integrated measurement signal, the evaluation period lying within the on-period; detecting the presence of a short circuit, if the integrated measurement signal during the evaluation period reaches a given reference value.

A second aspect relates to a further method for detecting a short circuit in a load current path, the load current path including an inductive load. The method comprises: applying a pulse-width modulated supply voltage to the load path, the supply voltage alternatingly assuming a high voltage level for an on-period and a low voltage level for an off-period; measuring a current flowing in the load path and providing a measurement signal being dependent on this current; differentiating the measurement signal during an evaluation period for obtaining a differentiated measurement signal, the evaluation period lying within the on-period; detecting the presence of a short circuit, if the differentiated measurement signal during the evaluation period reaches a given reference value.

A third aspect relates to a current controller comprising: load terminals for connecting an inductive load; a switching circuit being adapted for applying a pulse-width modulated supply voltage to the load terminals, the supply voltage alternatingly assuming a first voltage level during an on-period and a second voltage level during an off-period; a current measurement circuit being adapted for measuring a current flowing between the load terminals and being adapted for providing a current measurement signal that is dependent on the current; an evaluation circuit receiving the current measurement signal. The evaluation circuit is adapted: to integrate the measurement signal over an evaluation period for obtaining an integrated measurement signal, the evaluation period lying within the on-period; to compare the integrated measurement signal with a reference value; and to disable the switching circuit, if the integrated measurement signal reaches the reference value within the evaluation period.

A fourth aspect relates to a further current controller comprising: load terminals for connecting an inductive load; a switching circuit being adapted for applying a pulsewidth-modulated supply voltage to the load terminals, the supply voltage alternatingly assuming a first voltage level during an on-period and a second voltage level during an off-period; a current measurement circuit being adapted for measuring a current flowing between the load terminals and being adapted for providing a current measurement signal that is dependent on the current; an evaluation circuit receiving the current measurement signal. The evaluation circuit is adapted: to differentiate the measurement signal over an evaluation period for obtaining a differentiated measurement signal, the evaluation period lying within the on-period; to compare the differentiated measurement signal with a reference value; and to disable the switching circuit, if the differentiated measurement signal reaches the reference value within the evaluation period.

### BRIEF DESCRIPTION OF THE DRAWINGS

Examples will now be explained with reference to drawings. These drawings serve to illustrate the basic principle of the present invention. Thus, only aspects necessary for understanding this basic principle are illustrated. The drawings are not to scale. In the drawings the same reference characters designate the same features with the same meaning.

FIG. 1 is a block diagram of a current controller that includes terminals for connecting an inductive load, a switching circuit for applying a pulse-width modulated voltage to the load terminals, and an evaluation circuit;

FIG. 2 illustrates timing diagrams of signals occurring in the current controller of FIG. 1;

FIG. 3 illustrates a first method for detecting a short circuit in the load path that includes the inductive load;

FIG. 4 is a block diagram of an example of an evaluation circuit performing the method according to FIG. 3;

FIG. 5 illustrates an example of an analog integrating circuit of the evaluation circuit of FIG. 4;

FIG. 6 illustrates an example of a digital integrating circuit of the evaluation circuit of FIG. 4;

FIG. 7 illustrates an example of a timing circuit of the evaluation circuit of FIG. 4;

FIG. 8 illustrates the functionality of the timing circuit of FIG. 7 by way of timing diagrams;

FIG. 9 illustrates a first example of a control circuit of the switching circuit according to FIG. 1;

FIG. 10 illustrates a second example of a control circuit;

FIG. 11 illustrates the functionality of a current controller having an evaluation circuit according to FIG. 4 and a control circuit according to FIG. 10 by way of timing diagrams;

FIG. 12 illustrates a further example of an evaluation circuit; and

FIG. 13 illustrates an example of a differentiating circuit of the evaluation circuit of FIG. 12.

### DETAILED DESCRIPTION OF ILLUSTRATIVE EMBODIMENTS

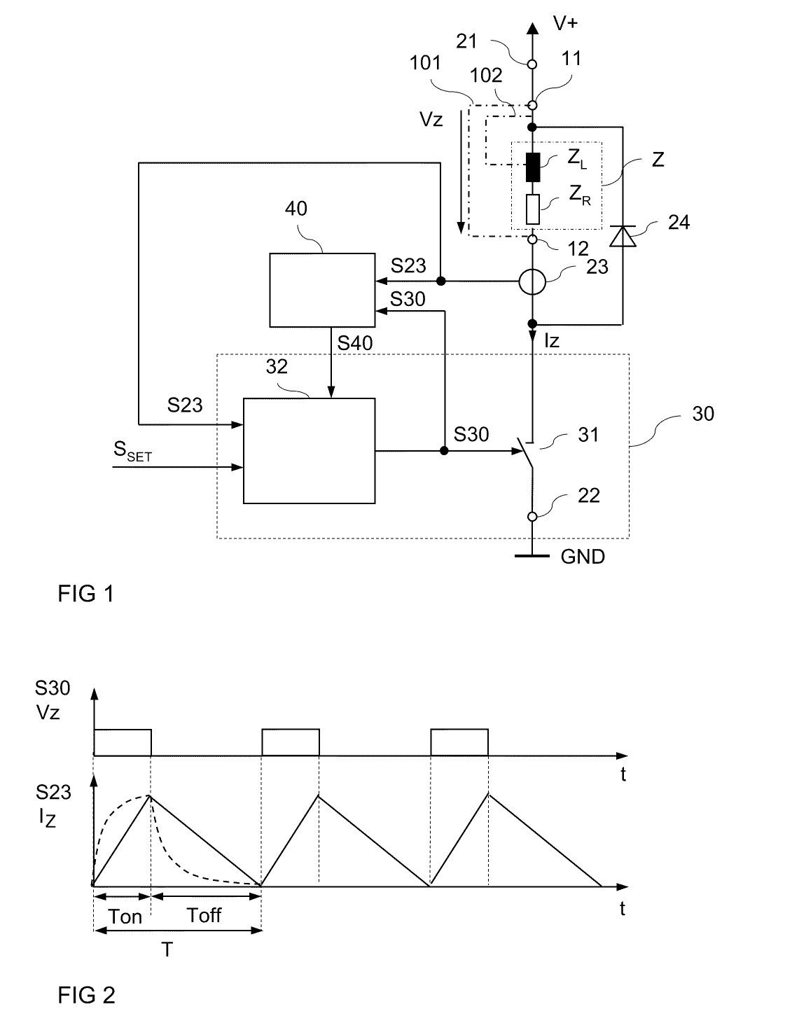

FIG. 1 shows a block diagram of an example of a current controller. The current controller includes load terminals 11, 12 for connecting an inductive load Z (shown in dashed lines). It should be noted that an “inductive load” in connection with the present disclosure is any load having an inductive load component. Besides the inductive load component the load may, of course, include resistive (ohmic) and/or capacitive load components. In the example illustrated in FIG. 1, load Z includes an inductive load component Z_{L} and a resistive load component Z_{R} that lies in series to the inductive load component Z_{L}. Inductive loads are, for example, but are not restricted to, coils of magnetic valves, like valves that are used in combustion machines for injecting fuel.

The current controller further includes supply terminals 21, 22 for applying a supply voltage. In operation of the current controller a first supply potential V+, which will also be referred to as a positive supply potential, is applied to a first one 21 of the supply terminals, and a second supply potential GND, which will be referred to as negative supply potential or ground, is connected to a second one 22 of the supply terminals. A voltage present between the first and second supply terminals 21, 22 will be referred to as supply voltage.

The current controller further comprises a switching circuit 30 that is adapted for applying a pulse-width modulated supply voltage Vz to the load Z, i.e., between the load terminals 11, 12. In the example according to FIG. 1 the switching circuit 30 includes a switching element 31 that has a load path and a control terminal, and that has its load path connected between one 12 of the load terminals and one 22 of the supply terminals. The other one 11 of the load terminals and the other one 21 of the supply terminals are connected to one another or are formed by the same circuit node. The switching circuit 30 further includes a control circuit 32 that is adapted to provide a pulse-width modulated control signal S30, the control signal S30 being received at the control terminal of switching element 31. Controlled by control signal S30 switching element 31 alternatingly assumes two different switching states: A first switching state, in which switching element 31 is switched on (conducts) and which will be referred to as on-state in the following; and a second switching state, in which switching element 31 is off (blocks) and which will be referred to as off-state in the following. A signal level of control signal S30 that results in the switching element 31 being in its on-state will be referred to as on-level in the following, and a signal level of control signal S30 resulting in the switching element 31 being in its off-state will be referred to as off-level in the following.

Depending on the switching state of switching element 31 the pulse-width modulated supply voltage applied to the load Z assumes one of two different voltage levels: A first voltage level, if switching element 31 is in its on-state; a second voltage level, if the switching element 31 is in its off-state. Assuming that a voltage drop across the switch-on switching element 31 and across a measurement circuit 23, which will be explained in the following, are negligible, then the first voltage level approximately corresponds to the supply voltage applied between the supply terminals 21, 22. A second voltage level is approximately zero or corresponds to the forward voltage of a free-wheeling diode 24 that is optionally connected in parallel to the load Z and that is, therefore, connected between the load terminals 11, 12.

Switching element 31 is, for example, a MOS-transistor, like a MOSFET or an IGBT. The load path of such MOS-transistors is formed by their drain-source-path, while a control terminal is formed by their gate terminals.

The current controller further includes a current measurement circuit 23 that is adapted to measure a load current Iz flowing between load terminals 11, 12. Current measurement circuit 23 may be any circuit that is suitable for measuring the load current Iz and providing a current measurement signal S23, that is dependent on the load current Iz. The current measurement signal S23 is, in particular, proportional to load current Iz. Current measurement circuit 23 may, for example, include a shunt-resistor that is connected in series to the switching element 31. If a current measurement circuit 23 including a shunt-resistor is used, a voltage drop across the shunt-resistor may be used as the current measurement signal S23, such voltage drop being proportional to the current flowing through the shunt-resistor. It goes without saying, that any other current measurement circuit 23 may also be used. There are specific MOSFETs that have an integrated current measurement circuit using so-called sense-FETs. These specific MOSFETs are suitable for switching current through a load and for providing a current measurement signal. It goes without saying that such a specific MOSFET may be applied in the current controller of FIG. 1, with this MOSFET acting as the switching element 31 and as the current measurement circuit 23.

Control circuit 32 receives the current measurement signal S23 and a set signal S_{SET} and is adapted to adjust the duty cycle of control signal S30 dependent on the current measurement signal S23 and the set signal S_{SET}. The duty cycle DC of control signal S30 is determined by the relationship between the duration of the on-period Ton and the duration T of one switching cycle, where one switching cycle includes an on-period having a duration Ton and an off-period having a duration Toff. Duty cycle DC therefore is:

DC=Ton/(Ton+Toff)=Ton/T (1)

Control circuits 32 that generate a pulse-width modulated control signal, like signal S30, dependent on a current measurement signal, like signal S23, and a set signal, like signal S_{SET}, for a switching element, like switching element 31, in a current controller are known, so that detailed explanations are not necessary.

The basic principle of the current controller according to FIG. 1 becomes apparent from FIG. 2, in which timing diagrams of control signal S30 and the current Iz or the current measurement signal S23, respectively, are shown. For explanation purposes it may be assumed that the pulse-width supply voltage Vz has a high signal level if control signal S30 assumed its on-level, and that the supply voltage Vz has a low voltage level, if the control signal S30 assumes its off-level. In the example according to FIG. 2 the on-level of control signal S30 is a high-signal level, while the off-level of the control signal S30 is a low-signal level.

FIG. 2 illustrates the control signal S30 (or supply voltage Vz, respectively) and the current measurement signal S23 for a number of switching cycles. The current measurement signal S23 for explanation purposes is assumed to be proportional to load current Iz. The timing diagram illustrated in FIG. 2 for current measurement signal S23 therefore basically also applies to the load current Iz.

Each switching cycle includes an on-period having a duration Ton, in which control signal S30 assumes an on-level, so that the supply voltage Vz assumes its high-voltage level, and an off-period, in which the control signal S30 assumes its off-level, so that the supply voltage Vz assumes its low-voltage level.

The current Iz through the load Z increases during the on-period and subsequently decreases during the off-period. If the controller is in its steady state the increase in the current Iz during the on-period equals the decrease in the current Iz during the off-period. A mean-value of the load current Iz may be adjusted by temporarily changing the duty cycle of the control signal S30, as it is generally known.

The current controller of FIG. 1 further includes an evaluation circuit 40 that receives the current measurement signal S23 and that is adapted to detect a short circuit in the load path between load terminals 11, 12. Two examples for short circuit scenarios are illustrated in FIG. 1 in dash-dotted lines. In a first scenario 101 the load terminals 11, 12 are short circuited. In a second scenario 102 load Z is partly short circuited, i.e., a number of windings (not shown) of the inductive load Z are short circuited, resulting in a reduction of the inductive and the resistive load component Z_{L}, Z_{R}. Each of these short circuit scenarios reduces the inductivity that is seen between load terminals 11, 12. In the first scenario the inductivity is approximately zero or equals the inductivity of a wire connection between the load terminals 11, 12. In the second scenario the inductivity is a share of the “normal” inductivity of the load Z, the normal inductivity being the inductivity of the load Z, if no short circuit occurs.

The explained reduction of inductivity in case of short circuit results in a faster increase of the current Iz or the current measurement signal S23, respectively, during the on-period as compared to the normal state, when no short circuit is present.

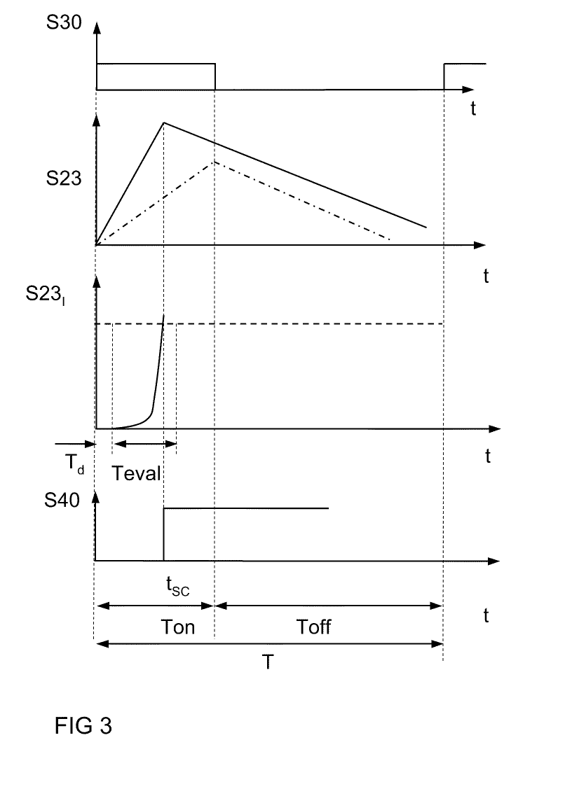

The functionality of the evaluation circuit 40 for detecting a short circuit condition in the load path will be explained with reference to timing diagrams illustrated in FIG. 3. In this connection it should be mentioned that for simplicity of illustration the load current Iz is assumed to increase and decrease linearly during the on- and off-periods. This assumes that saturation effects of the inductive load do not play a role. In case such saturation effects occur, the increase and decrease of the load current will no longer be linear as it is illustrated in dashed-dotted lines in FIG. 1. However, the functionality of the evaluation circuit is independent of the load current Iz increasing linearly or non-linearly during the on-period.

For detecting a short circuit condition evaluation circuit 40 is adapted to integrate current measurement signal S23 during an evaluation period having a duration Teval and to compare the integrated current measurement signal S23_{I} with a reference value S_{REF}, where the presence of a short circuit is detected, if the integrated current measurement signal S23_{I} reaches or rises above the reference value S_{REF} during the evaluation period Teval.

FIG. 3 illustrates the control signal S30, the current measurement signal S23 and the integrated current measurement signal S23_{I} for one switching cycle under a short circuit condition. In this case current measurement signal S23 rises faster during the on-period as compared to the normal state, the timing diagram of the current measurement signal S23 in the normal state being illustrated in dashed-dotted lines in FIG. 3. The evaluation period Teval lies within on-period Ton, i.e., the evaluation period Teval starts with the on-period or starts delayed as compared to the beginning of the on-period, and ends with the on-period or ends earlier than the on-period.

In the example according to FIG. 3 the evaluation period Teval starts delayed with a delay time Td as compared to the start of the on-period. This has the advantage that current spikes that may occur after the beginning of the on-period, i.e., after switch (31 in FIG. 1) has been switched on, do not influence the short circuit detection. Delay time Td is particularly selected such that it is longer than the time period for which current spikes may occur after the beginning of the on-period. The presence of a short circuit is detected, if the integrated current measurement signal S23_{I} reaches the reference value S_{REF}, which occurs at time t_{SC} in FIG. 3.

Referring to FIG. 1 evaluation circuit 40 provides a status signal S40, this status signal S40 has a signal level that is dependent on whether a short circuit has been detected or has not been detected. For illustration purposes it may be assumed that status signal S40 has a low-signal level, if no short circuit has been detected, and has a high-signal level, which will also be referred to as a short circuit level, if a short circuit has been detected. The status signal S40 may be used to protect the current controller in a number of different ways.

First, status signal S40 may be provided to the control circuit 32, as it is shown in FIG. 1, and may disable control circuit 32. Disabling the control circuit 32 results in switching off switching element 31.

Second, status signal S40 may be used to interrupt the voltage supply of the current controller. This may be performed by using an additional switch (not shown) that is connected at any position between the supply terminals 21, 22.

Third, the status signal may be provided to an overall control circuit (not shown) that controls the current controller (and possible additional current controllers) and that is adapted to take further protection means in case a short circuit is detected.

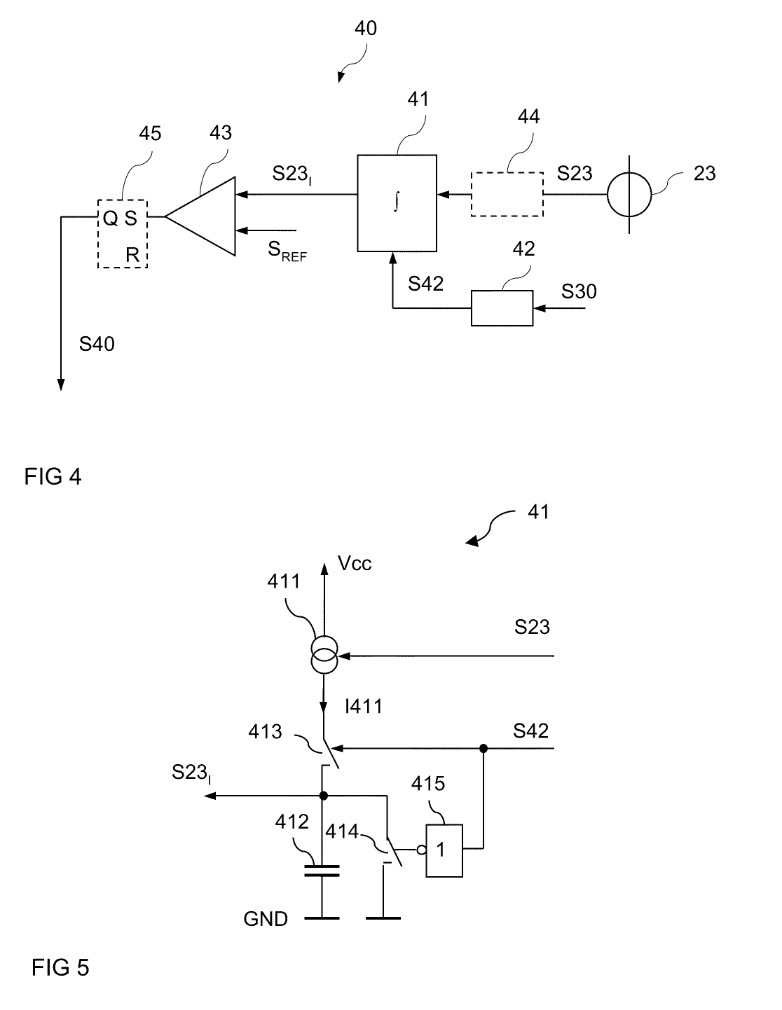

FIG. 4 illustrates an example of the evaluation circuit 40. The evaluation circuit 40 has an integrating circuit 41 that receives the current measurement signal S23 and that receives a timing signal S42. The evaluation circuit 40 is adapted to integrate current measurement signal S23 for the evaluation period (Teval in FIG. 3), where the evaluation period is determined by timing signal S42. Timing signal S42 is generated by a timing circuit 42 dependent on the control signal S30. A comparator 43 receives the integrated measurement signal S23_{I} provided by the integrating circuit 41 and reference signal S_{REF} at its inputs provides status signal S40 at its output. In the example according to FIG. 4, comparator 43 receives the integrated signal current measurement signal S23_{I} at its non-inverting and the reference signal S_{REF} at its inverting input. Reference signal S_{REF} is provided by a reference signal source (not shown).

Optionally the output signal of the comparator 43 is provided to a register, like a flip-flop, where the status signal S40 is the output signal of the register 45. Using a register 45 ensures that the status signal S40 keeps a short circuit level after a short circuit has been detected, even if the integrated current measurement signal S23_{I} falls below the reference signal S_{REF} later on, for example, after switching element 31 has been switched off.

The evaluation circuit 40 may be realized as an analog circuit that includes analog circuit components, or as a digital circuit that includes digital circuit components. An example of an analog integrating circuit 41 is illustrated in FIG. 5. This integrated circuit includes a series circuit having a controllable current source 411, a capacitor 412 and a switching element 413. Controllable current source 411 receives current measurement signal S23 as a control signal and provides a current I411 that is dependent on the current measurement signal S23, and that is in particular proportional to the current measurement signal S23. Switch 413 is controlled by timing signal S42 in such a way that it is closed during the evaluation period. A further switching element 414 that is connected in parallel to the capacitor 412 serves to discharge the capacitor 412 prior to the beginning of the evaluation period. For this purpose the further switching element 414 is controlled by a signal that is complementary to the timing signal S42. In the example according to FIG. 5 a control signal of the further switching element 414 is generated from the timing signal S42 using an inverter 415.

In the integrating circuit according to FIG. 5 the integrated current measurement signal S23_{I} is the voltage across the capacitor 412. This voltage increases during the evaluation period as capacitor 412 is charged via switching element 413 with a current I411 that is dependent on the current measurement signal S23.

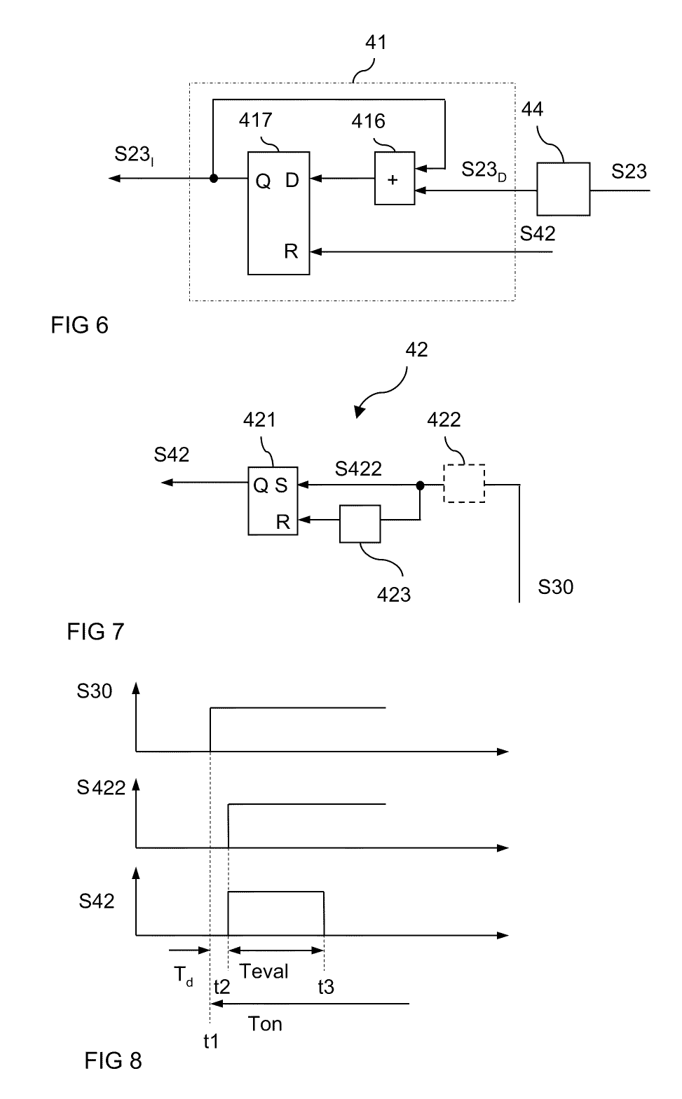

An example for a digital integrating circuit 41 is illustrated in FIG. 6. This circuit receives a digital current measurement signal S23_{D}. Digital current measurement signal S23_{D} is generated using an analog-to-digital converter (A/D-converter) 44 from the current measurement signal S23 as provided by the current measurement circuit (23 in FIG. 1). The integrating circuit 41 includes an adder 416 and a register 417 connected downstream to the adder 416. Adder 416 receives the digital current measurement signal S23_{D} and the integrated current measurement signal S23_{I} that is available at an output Q of register 417. Adder 416 and register 417 together form an integrator or accumulator.

The digital current measurement signal S23_{D} includes a series of current measurement values that are accumulated using adder 416 and register 417 in order to form the integrated current measurement signal S23_{I}. In order to ensure that current measurement values are only accumulated during the evaluation period register 417 has a reset input R that receives timing signal S42, register 417 being reset by timing signal S42 for time periods that are outside the evaluation period, so that a new integration/accumulation process starts each time with the start of a new evaluation period.

FIG. 7 illustrates an example of a timing circuit 42 that receives control signal S30 and provides timing signal S42. The timing circuit according to the example includes a flip-flop 421 having a set S and a reset R input and an output Q, the timing signal S42 being the output signal of flip-flop 421. Control signal S30 is provided to the set input S of flip-flop 421 either directly or via an optional delay element 422. The optional delay element 422 determines the delay time Td (see FIG. 3) between the beginning of an on-period Ton and the beginning of the evaluation period Teval. The signal that is provided to the set input S of flip-flop 421 is provided to the reset input R via a second delay element 423, the second delay element 423 adjusting the duration of the evaluation period. The functionality of the timing circuit 42 of FIG. 7 is illustrated in FIG. 8 using timing diagrams of the control signal S30, the signal S422 provided to the set input of flip-flop 421, and the timing signal S42. For explanation purposes it may be assumed that a high-signal level of control signal S30 represents the on-period, so that a rising edge of control signal S30 indicates the beginning of the on-period, and that a high-signal level of timing signal S42 represents the evaluation period Teval, so that the rising edge of the timing signal S42 represents the beginning of the evaluation period Teval. In FIG. 8 t1 is the time when the on-period starts, i.e., when a rising edge of control signal S30 occurs. Assuming that there is a first delay element 422, then flip-flop 421 is set at time t2, time t2 being delayed by delay time Td as compared to time t1. The evaluation period starts at time t2 and ends at a later time t3, the duration of the evaluation period Teval which is the time difference between times t3 and t2 is determined by the delay time of second delay element 423.

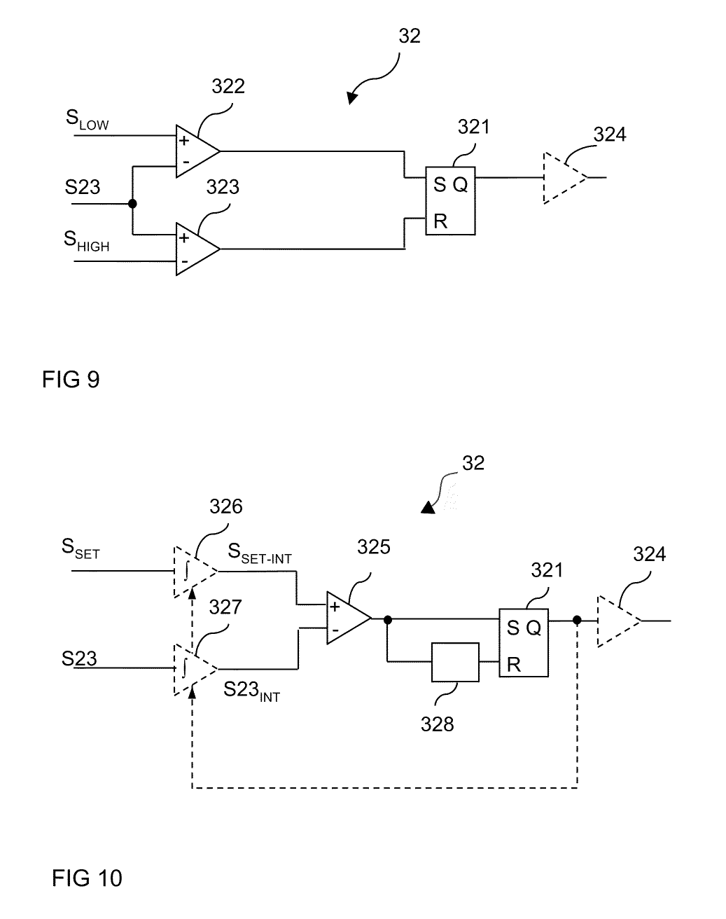

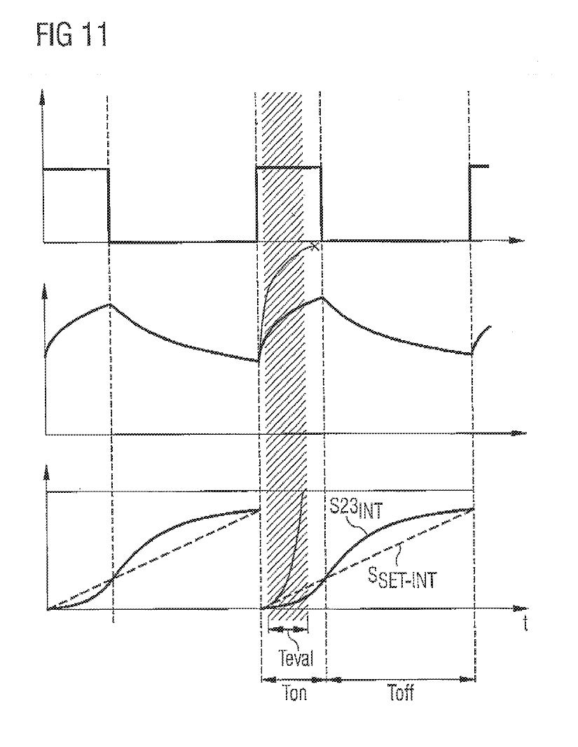

The evaluation circuit 40 is not restricted to be used in connection with a particular switching circuit 30 or with a particular control circuit 32 for a switch 31. However, any control circuit 32 that is adapted to provide a pulse-width modulated control signal dependent on a current measurement signal S23 and dependent on a set signal S_{SET} may be used in connection with the evaluation circuit 40. Only for explanation purposes two different control circuits will shortly be explained with reference to FIGS. 9 and 10. Such control circuits 32 are also referred to as controllers.

FIG. 9 illustrates a so-called hysteretic controller. This controller 32 generates an on-level of control signal S30 each time when measurement signal S23 reaches or falls below a lower signal level S_{LOW}, and generates an off-level of control signal S30 each time current measurement signal S23 reaches or rises above a high-signal level S_{HIGH}. The difference between the high and the low signal level S_{HIGH}, S_{LOW} is the hysteresis of the controller, that may have a fixed value. One of the high and low signal levels S_{HIGH}, S_{LOW} is dependent on the set value S_{SET}, with the set value S_{SET} and the hysteresis determining the mean value of the current flowing through the load.

Hysteretic controller of FIG. 9 includes a flip-flop 321 that is set by a first comparator 322 each time the current measurement signal S23 reaches the low-signal level S_{LOW} and that is reset by a second comparator 323 each time current measurement signal S23 reaches the high-signal level S_{HIGH}. The control signal S30 is provided at an output Q of flip-flop 321. Optionally an amplifier or driver circuit 324 is connected downstream to flip-flop 321. This amplifier or driver circuit 324 serves to generate from the (logical) output signal of flip-flop 321 a signal that is suitable for driving switching element 31.

The control circuit 32 of FIG. 10 generates an on-level of control signal S30 for a fixed time each time the current measurement signal S23 reaches or falls below set signal S_{SET}. This controller 32 has an output flip-flop 321 that is set by an output signal of a comparator 325, this comparator 325 receiving the current measurement signal S23 and the set signal S_{SET}. Output flip-flop 321 is reset by the output signal of a delay element 328 after a given delay time after the output flip-flop 321 has been set. The delay time of delay element 328 determines the fixed on-period of this controller.

Alternatively flip-flop 321 is not set dependent on the current measurement signal S23 and the set signal S_{SET} but is set dependent on an integrated current measurement signal S23_{INT} and an integrated set signal S_{SET-INT}. Integration of current measurement signal S23 and set signal S_{SET} is performed by optional integrators 326, 327, that receive the current measurement signal S23 and the set signal S_{SET} and that provide the integrated signals S23_{INT}, S23_{SET-INT}, these integrated signals S23_{INT}, S23_{SET-INT} being provided to the inputs of comparator 325 in this case.

FIG. 11 illustrates the functionality of a current controller that includes an evaluation circuit as illustrated in FIG. 4 and an integrating controller 32 as illustrated in FIG. 10. In FIG. 11 timing diagrams of the control signal S30, the current measurement signal S23, the integrated set signal S_{SET-INT} and the integrated current measurement signal S23_{INT} are illustrated. In this current controller the duration of the on-period Ton is constant. The on-period starts each time, the integrated current measurement signal S23_{INT} falls to the level of the integrated set signal S_{SET-INT}.

For one of the switching cycles illustrated in FIG. 11 a short circuit scenario is illustrated in dashed-lines. In this scenario the current, and therefore the current measurement signal S23, increases rapidly after the begin of the on-period Ton. For this scenario The integrated current measurement signal S23_{INT} that is obtained by integrating the current measurement signal S23 during the evaluation period Teval reaches the reference value S_{REF}, thereby indicating that a short circuit has occurred.

Alternatively to integrating the current measurement signal S23 during the evaluation period the current measurement signal S23 may be differentiated during the evaluation period, where a differentiated current measurement signal S23′ that is obtained by differentiating the current measurement signal S23 may be compared to a reference value S_{REF}′. The presence of a short circuit is detected, if the differentiated current measurement signal S23′ reaches the reference value S_{REF}′ during the evaluation period Teval. Concerning the duration and the start of the evaluation period anything that has been discussed above applies equivalently. As already discussed above a short circuit in the load path results in a reduction of the inductivity that is seen between the load terminals 11, 12. This reduction of inductivity results in a faster increase of the load current Iz, and therefore the current measurement signal S23. Instead of integrating the current measurement signal S23 such fast increase may be detected by differentiating the current measurement signal S23 and comparing the differentiated current measurement signal S23′ to the reference value S_{REF}′.

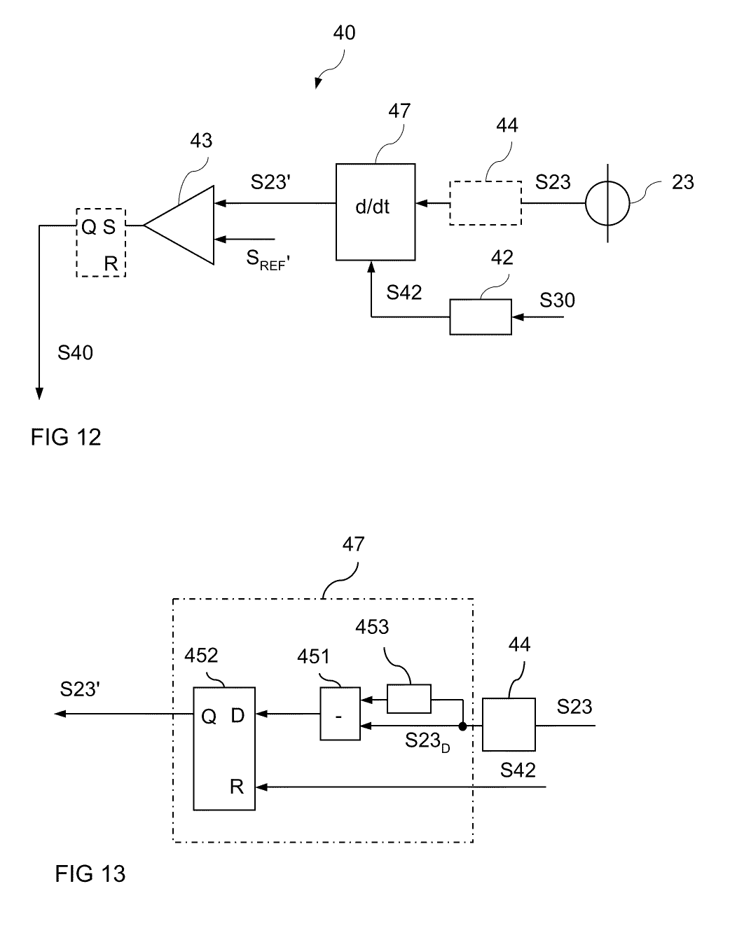

An example of an evaluation circuit 40 for detecting a short circuit on the basis of differentiating the current measurement signal S23 is illustrated in FIG. 12. This evaluation circuit 40 according to FIG. 12 is different from the evaluation circuit according to FIG. 4 only in that integrating circuit 41 is replaced by a differentiating circuit 47. The differentiating circuit 47 receives the current measurement signal S23 and the timing signal S42, with the timing signal S42 determining the evaluation period, i.e., the period in which the differentiating circuit 47 differentiates the current measurement signal S23 in order to provide the differentiated current measurement signal S23′.

The evaluation circuit 40, in particular the differentiating circuit 47, may be realized using analog or digital circuit components.

FIG. 13 illustrates an example of a digital differentiating circuit 47. This differentiating circuit receives a digital current measurement signal S23_{D} that is obtained from the current measurement signal S23 by analog-to-digital conversion using A/D-converter 44. The differentiating circuit 47 includes a subtractor 451 that receives the digital current measurement signal S23_{D} at a first input and a delayed current measurement signal at a second input. Delayed current measurement signal is available at the output of a delay element 453 that receives the current measurement signal S23_{D}. The delay time of the delay element is selected such that at the two inputs of subtractor 451 to subsequent current measurement values are present.

An output signal of subtractor 451 is provided to a data input of the register 452 that provides the differentiated current measurement signal S23′ at its output. Register 452 has a reset input that receives the timing signal S42. The timing signal S42 resets register 452 in times that are outside evaluation period Teval.

Finally it should be noted that features that have been explained with reference to one figure may be combined with any other features that have been illustrated with another figure, even in those cases in which this has not explicitly been mentioned.

What is claimed is:

1. A method for detecting a short circuit in a load current path that includes an inductive load, the method comprising:
applying a pulse-width modulated supply voltage to the load current path, the supply voltage alternatingly assuming a first voltage level for an on-period and a second voltage level for an off-period;
measuring a current flowing in the load current path and providing a measurement signal that is dependent on this current;
integrating the measurement signal over an evaluation period for obtaining an integrated measurement signal, the evaluation period lying within the on-period; and
detecting the presence of a short circuit if the integrated measurement signal during the evaluation period reaches a given reference value.

2. The method of claim 1, wherein the evaluation period is shorter than the on-period.

3. The method of claim 2, wherein the evaluation period starts after a first delay time after the start of the on-period.

4. The method of claim 1, wherein applying the pulse-width modulated supply voltage to the load current path comprises:
connecting a switching element in series to the load current path to form a series circuit;
connecting the series circuit between terminals for a constant supply voltage;
alternatingly switching the switching element on for the on-period and off for the off-period.

5. A method for detecting a short circuit in a load current path that includes an inductive load, the method comprising:
applying a pulse-width modulated supply voltage to the load current path, the supply voltage alternatingly assuming a high voltage level for an on-period and a low voltage level for an off-period;
measuring a current flowing in the load current path and providing a measurement signal that is dependent on this current;
differentiating the measurement signal during an evaluation period to obtain a differentiated measurement signal, the evaluation period lying within the on-period; and
detecting the presence of a short circuit, if the differentiated measurement signal during the evaluation period reaches a given reference value.

6. The method of claim 5, wherein the evaluation period is shorter than the on-period.

7. The method of claim 6, wherein the evaluation period starts after a first delay time after the start of the on-period.

8. The method of claim 5, wherein applying the pulse-width modulated supply voltage to the load current path comprises:
connecting a switching element in series to the load current path to form a series circuit;
connecting the series circuit between terminals for a constant supply voltage; and
alternatingly switching the switching element on for the on-period and off for the off-period.

9. A current controller comprising:
load terminals for connecting an inductive load;
a switching circuit adapted to apply a pulsewidth-modulated supply voltage to the load terminals, the supply voltage alternatingly assuming a first voltage level during an on-period and a second voltage level during an off-period;
a current measurement circuit adapted to measure a current flowing between the load terminals and adapted to provide a current measurement signal that is dependent on the current; and
an evaluation circuit receiving the current measurement signal and being adapted:
to integrate the current measurement signal over an evaluation period to obtain an integrated measurement signal, the evaluation period lying within the on-period;
to compare the integrated measurement signal with a reference value; and
to disable the switching circuit if the integrated measurement signal reaches the reference value within the evaluation period.

10. The current controller of claim 9, wherein the evaluation circuit is adapted to start integrating the current measurement signal after a delay time after the on-period has started.

11. The current controller of claim 9, wherein the evaluation circuit is adapted to adjust the evaluation period to be shorter than the on-period.

12. The current controller of claim 9, wherein the switching circuit comprises:
supply terminals for supplying a constant supply voltage;
a switch having a load path and a control terminal, the load path being coupled between one of the supply terminals and one of the load terminals; and
a control circuit adapted to provide a pulsewidth-modulated control signal to the control terminal of the switch.

13. The current controller of claim 12, wherein the control circuit receives the current measurement signal and a set-signal and is adapted to adjust a duty-cycle of the control signal dependent on the current measurement signal and the set-signal.

14. A current controller comprising:
load terminals for connecting an inductive load;
a switching circuit adapted to apply a pulsewidth-modulated supply voltage to the load terminals, the supply voltage alternatingly assuming a first voltage level during an on-period and a second voltage level during an off-period;
a current measurement circuit adapted to measure a current flowing between the load terminals and adapted to provide a current measurement signal that is dependent on the current; and
an evaluation circuit receiving the current measurement signal and being adapted:
to differentiate the current measurement signal over an evaluation period for obtaining a differentiated measurement signal, the evaluation period lying within the on-period;
to compare the differentiated measurement signal with a reference value; and
to disable the switching circuit if the differentiated measurement signal reaches the reference value within the evaluation period.

15. The current controller of claim 14, wherein the evaluation circuit is adapted to start integrating the current measurement signal after a delay time after the on-period has started.

16. The current controller of claim 14, wherein the evaluation circuit is adapted to adjust the evaluation period to be shorter than the on-period.

17. The current controller of claim 14, wherein the switching circuit comprises:
supply terminals for supplying a constant supply voltage;
a switch having a load path and a control terminal, the load path being coupled between one of the supply terminals and one of the load terminals; and
a control circuit adapted to provide a pulsewidth-modulated control signal to the control terminal of the switch.

18. The current controller of claim 17, wherein the control circuit receives the current measurement signal and a set-signal and is adapted to adjust a duty-cycle of the control signal dependent on the current measurement signal and the set-signal.
